(19) United States
(12) Patent Application Publication
(10) Pub. No.: US 2025/0277303 A1
(43) Pub. Date: Sep. 4, 2025

(54) LOW-TEMPERATURE VAPORIZER FOR ION IMPLANTER WITH IN-VACUUM CONTROLLED FLOW

(71) Applicant: Axcelis Technologies, Inc., Beverly, MA (US)

(72) Inventors: Neil James Bassom, Hamilton, MA (US); Neil Colvin, Merrimack, NH (US); Paul Silverstein, Shrewsbury, MA (US); Scott Knight Batchelder, Newburyport, MA (US); Atul Gupta, Lexington, MA (US)

(21) Appl. No.: 19/063,918

(22) Filed: Feb. 26, 2025

Related U.S. Application Data
(60) Provisional application No. 63/560,132, filed on Mar. 1, 2024.

(51) Int. Cl. C23C 14/48; C23C 14/54

(52) U.S. Cl. CPC C23C 14/48; C23C 14/54

(57) ABSTRACT

An ion source for an ion implantation system has a vacuum enclosure defining a vacuum environment and an arc chamber defining an arc chamber environment. The arc chamber is positioned within the vacuum enclosure and has an arc chamber conduit in fluid communication with the arc chamber environment. A vaporizer is positioned within the vacuum enclosure and configured to selectively vaporize a dopant species to define a dopant vapor within a vaporizer environment. The vaporizer has a vaporizer conduit in fluid communication with the vaporizer environment. A valve within the vacuum enclosure is fluidly coupled to the arc chamber conduit and the vaporizer conduit. The valve is configured to selectively control a flow of the dopant vapor from the vaporizer environment to the arc chamber environment. The valve can be a solenoid valve controlled by a controller. Multiple vaporizers and valves can be provided for vaporizing multiple dopant species.

### REFERENCE TO RELATED APPLICATIONS

This application claims the benefit of U.S. Provisional Application Ser. No. 63/560,132 filed Mar. 1, 2024, entitled, “LOW-TEMPERATURE VAPORIZER FOR ION IMPLANTER WITH IN-VACUUM CONTROLLED FLOW”, the contents of which are herein incorporated by reference in their entirety.

### TECHNICAL FIELD

The present invention relates generally to ion implantation systems, and more specifically to an ion source having a valve configured to control a flow of dopant vapor between a vaporizer and an arc chamber.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n-or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

Conventionally, an ion source of an ion implantation system can comprise a vaporizer configured to heat and vaporize a dopant material for use in the formation of the ions. Power supplied to the ion source is typically approximately 1-1.5 kW, whereby an arc chamber within the ion source can operate at elevated temperatures exceeding 600° C. In an ion source having a vaporizer positioned within the ion source, the vaporizer is in continuous fluid communication with the arc chamber, whereby heat from the arc chamber can heat the vaporizer, regardless of whether a heater associated with the vaporizer is operated.

As such, the minimum temperature at which the vaporizer in the conventional ion source can be maintained is subject to the temperature at which the arc chamber is operated within the ion source. Dopant materials having appreciable vapor pressure at very low temperatures (up to about 100° C.) can be very difficult to use, regardless of other desirable properties of such materials, as they will continuously evolve material into the arc chamber when the arc chamber is operated at elevated temperatures. For example, materials of interest in the power device industry, such as AlI₃ and AlCl₃, may exhibit appreciable vapor pressure at such elevated temperatures, leading to cross-contamination when operating with other species in the conventional ion source.

### SUMMARY

The following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

Aspects of the disclosure facilitate ion implantation processes for implanting ions into a workpiece. According to one exemplary aspect, an ion implantation system is provided having an ion source configured to form an ion beam, a beamline assembly configured to selectively transport the ion beam, and an end station configured to accept the ion beam for implantation of the ions into a workpiece.

In accordance with one exemplary aspect, the ion source comprises a vacuum enclosure defining a vacuum environment therein. An arc chamber generally defines an arc chamber environment therein, wherein the arc chamber is positioned within the vacuum enclosure and comprises an arc chamber conduit in fluid communication with the arc chamber environment. A first vaporizer is positioned within the vacuum enclosure and configured to selectively vaporize a first dopant species to define a first dopant vapor within a first vaporizer environment. The first vaporizer, for example, comprises a first vaporizer conduit in fluid communication with the first vaporizer environment. Further, a first valve is positioned within the vacuum enclosure and fluidly coupled to the arc chamber conduit and the first vaporizer conduit. The first valve, for example, is configured to selectively control a flow of the first dopant vapor from the first vaporizer environment to the arc chamber environment.

In one embodiment, the ion source further comprises a controller, wherein the first valve comprises a first automated valve. Accordingly, the controller is configured to control the first automated valve to selectively control the flow of the first dopant vapor from the first vaporizer environment to the arc chamber environment. The control of the first automated valve, for example, is based, at least in part, on one or more desired arc chamber conditions associated with the arc chamber.

The first automated valve, for example, can comprise a first solenoid valve, and the controller can be configured to control a duty cycle of the first solenoid valve, thereby selectively controlling the flow of the first dopant vapor from the first vaporizer environment to the arc chamber environment. The flow of the first dopant vapor from the first vaporizer environment to the arc chamber environment, for example, can be selectively variable between zero and 100%. A maximum operating frequency, or switching frequency, for example, can be on the order of hundreds of Hertz.

In one example, the first solenoid valve comprises a ball and a sealing surface configured to selectively flow the first dopant vapor from the first vaporizer environment to the arc chamber environment based on a position of the ball with respect to the sealing surface. In another example, the first automated valve comprises one of a hydraulic valve, a compression valve, or a butterfly valve.

In another example, the ion source can further comprise a second vaporizer positioned within the vacuum enclosure and configured to selectively vaporize a second dopant species to define a second dopant vapor within a second vaporizer environment defined therein. The second vaporizer can comprise a second vaporizer conduit in fluid communication with the second vaporizer environment. Further, a second valve positioned within the vacuum enclosure and fluidly coupled to the arc chamber and the second vaporizer conduit, wherein the second valve is configured to selectively control a flow of the second dopant vapor from the second vaporizer environment to the arc chamber environment.

The second valve can comprise a second automated valve, wherein the controller is further configured to control the second automated valve to selectively control the flow of the second dopant vapor from the second vaporizer environment to the arc chamber environment. The controller, for example, can be further configured to control a respective electrical input to the first automated valve and the second automated valve to respectively control the flow of the first dopant vapor from the first vaporizer environment to the arc chamber environment and the flow of the second dopant vapor from the second vaporizer environment to the arc chamber environment, wherein the control is based, at least in part, on one or more desired arc chamber conditions associated with the arc chamber.

The second automated valve, for example, can comprise a second solenoid valve, and the controller can be configured to control a respective duty cycle of the first solenoid valve and the second solenoid valve. As such, the controller can respectively control the flow of the first dopant vapor from the first vaporizer environment to the arc chamber environment and the flow of the second dopant vapor from the second vaporizer environment to the arc chamber environment. The switching frequency of the second solenoid valve can further be on the order of hundreds of Hertz. Further, the flow of the second dopant vapor from the second vaporizer environment to the arc chamber environment is selectively variable between zero and 100%.

In one example, the first dopant species is configured to define singly-charged ions in the arc chamber, and the second dopant species is configured to define multiply-charged ions in the arc chamber.

One or more of the first automated valve and the second automated valve can respectively comprise one of a hydraulic valve, a compression valve, or a butterfly valve. In another example, one or more of the first valve and the second valve can respectively comprise a manually actuated valve. The respective manually actuated valve, for example, can comprise one of a compression valve and a butterfly valve. One or more linkages can be operably coupled to the first valve and the second valve, wherein the one or more linkages are configured to be manually maneuvered by an operator. The one or more linkages, for example, can pass through the vacuum enclosure from the vacuum environment to an atmospheric environment.

In another embodiment, the first valve is configured to control the flow of the first dopant vapor from the first vaporizer environment to the arc chamber environment when a first vaporizer temperature associated with the first vaporizer environment is lower than a first predetermined temperature. Further, the first valve, for example, can be configured to selectively prevent the flow of the first dopant vapor from the first vaporizer environment to the arc chamber environment when the first vaporizer temperature is greater than the first predetermined temperature. The first predetermined temperature, for example, can be approximately 150° C.

The arc chamber, for example, can further heat the first vaporizer and the second vaporizer by one or more of conduction and radiation based, at least in part, on an arc chamber temperature associated with the arc chamber environment. The first valve and the second valve, for example, can be further configured to selectively control the flow of the first dopant vapor from the first vaporizer environment to the arc chamber environment and the flow of the second dopant vapor from the second vaporizer to the arc chamber environment, respectively, based on the arc chamber temperature.

The first valve and the second valve, for example, can be further configured to selectively control the flow of the first dopant vapor from the first vaporizer environment to the arc chamber environment and the second dopant vapor from the second vaporizer to the arc chamber environment, respectively, regardless of the arc chamber temperature.

In yet another embodiment, the first vaporizer can comprise a crucible and a crucible heater, wherein the crucible is configured to generally contain the first dopant species in one or more of a solid state and a liquid state, and wherein the crucible heater is configured to selective heat the crucible to a predetermined vaporization temperature. A vaporizer power supply can be operably coupled to the crucible heater and configured to control the predetermined vaporization temperature based on a power provided to the crucible heater by the vaporizer power supply.

Any number of power supplies can be operably coupled to the arc chamber and vaporizer. For example, a power supply can be configured to ionize the first dopant vapor within the arc chamber environment based on an arc current provided by the arc chamber power supply to the arc chamber. The arc chamber, for example, can comprise a cathode disposed in the arc chamber environment, wherein the arc chamber power supply can comprise a biasing power supply configured to electrically bias the cathode with respect to the arc chamber.

One or more of the first dopant species and second dopant species can comprise aluminum. For example, either dopant species can comprise AlCl₃, whereby the resulting dopant vapor comprises (AlCl₃), (AlCl₃)₂, or a mixture thereof.

In yet another example, a first relief valve is provided in selective fluid communication with the vacuum environment that is external to the arc chamber, wherein the first relief valve is configured to exhaust the first vaporizer to the vacuum environment when a first vaporizer pressure within the first vaporizer environment exceeds a predetermined pressure.

In another example, the ion source further comprises a dopant gas source comprising a dopant gas species, and a dopant gas conduit in selective fluid communication with the dopant gas source. A dopant gas valve can be configured to selectively fluidly couple the dopant gas source to the arc chamber via the dopant gas conduit. The dopant gas source, for example, can comprise a gas bottle containing the dopant gas species.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a block diagram of an ion implantation system having a valve-controlled flow of an ion source material in accordance with several examples of the present disclosure.

FIG. 2 is a block diagram of an ion source in accordance with another example of the present disclosure.

FIG. 3 is a block diagram of another ion source enclosure having a solenoid valve for controlling dopant vapor in accordance with another example of the present disclosure.

FIG. 4 is a block diagram of a single vaporizer ion source enclosure having a valve for controlling dopant vapor in accordance with another example of the present disclosure.

FIG. 5 is a block diagram of a single vaporizer and gas supply for an ion source enclosure having a valve for controlling dopant vapor in accordance with another example of the present disclosure.

FIG. 6 is a partial perspective view of a dual vaporizer ion source having a mechanical valve for controlling dopant vapor in accordance with another example of the present disclosure.

FIG. 7 is a partial perspective view of a mechanical valve for controlling dopant vapor in accordance with another example of the present disclosure.

FIG. 8 is a graph illustrating an example vapor pressure curve for aluminum chloride.

### DETAILED DESCRIPTION

The present disclosure is directed generally toward an ion implantation system and an ion source material associated therewith. More particularly, the present disclosure is directed toward an ion source having one or more controllable vaporizers positioned within an ion source enclosure and configured to selectively vaporize a solid source material to gaseous form and selectively provide the gaseous source material to an arc chamber for producing ions to electrically or otherwise modify silicon, silicon carbide, or other semiconductor substrates at various temperatures. Additionally, a controllable valve is respectively positioned between one or more vaporizers and an arc chamber inside a vacuum chamber of the ion implantation system. The controllable valve(s) within the ion source are configured provide operation in a low temperature regime (e.g., less than approximately 150° C.) and a high temperature regime (e.g., greater than approximately 150° C.) for various dopant species.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

An ion source for an ion implantation system can be operated by providing various sources of a dopant ion species to an arc chamber in which a plasma is formed from the dopant ion species. In an in-chamber approach, the dopant ion species can be provided as a target positioned inside the arc chamber, whereby the dopant ion species is sputtered or chemically etched from the target to be ionized in the plasma. Alternatively, in a gaseous approach, the dopant ion species can be supplied to the arc chamber in a gaseous form. The dopant ion species can be provided as a gas directly from a pressurized or sub-atmospheric gas bottle held in atmospheric conditions, whereby the gas is ionized in the arc chamber. In another example, a vapor may be formed by heating a container initially holding the dopant ion species in solid or liquid form, whereby vapor pressure is generated to provide the dopant ion species in a gaseous form to the arc chamber for ionization.

The present disclosure advantageously provides a vaporizer system that can be maintained within a body of the ion source, whereby the vaporizer system is configured to selectively prevent flow of the vapor into the arc chamber when the vapor is not desired to be present in the arc chamber. The present disclosure further advantageously provides an ability to quickly control the flow of the vapor from the vaporizer to the arc chamber, thus enabling fast transitions between singly-charged and multiply-charged ion species from the vaporizer, as well as between the vaporizer and other gas sources.

In accordance with the present disclosure, the vaporizer system comprises a valve that selectively fluidly couples the arc chamber to a vaporizer, whereby the valve and vaporizer are located within the enclosure of the ion source, and as such, exposed to the operating temperature of the ion source. A dopant material can thus be vaporized in a crucible of the vaporizer within the enclosure, whereby the resulting vapor can be selectively flowed to the arc chamber or fully prevented from entering the arc chamber based on a process recipe or other condition associated with the ion implantation system. As such, the temperatures within the vaporizer can exceed temperatures associated with vapor pressures of the dopant materials in the vaporizer while selectively preventing the resulting vapor from entering the arc chamber

Thus, the present disclosure enables the vaporizer to be maintained at the operating temperature while transitioning between dopant materials or dopant species. Further, any number of vaporizers can be positioned within the enclosure and selectively coupled to the arc chamber through a respective number of valves, whereby short transition times can again be achieved between various dopant materials (e.g., a plurality of dopant species) associated with each vaporizer while maintaining the ion source at the operating temperature. For example, a plurality of vaporizers can be provided inside an ion source enclosure, whereby the plurality of vaporizers can be maintained at a plurality of different temperatures. Such a configuration, for example, can advantageously provide a first temperature suitable for single-charged operation of the ion source, and a second temperature suitable for multiply-charged operation of the ion source. The present disclosure further minimizes a loss of dopant material from the vaporizer via the valve, as dopant materials that have a substantial vapor pressure at temperatures that are lower than the desired operating temperature can be utilized, thus further minimizing cross-contamination of the plasma.

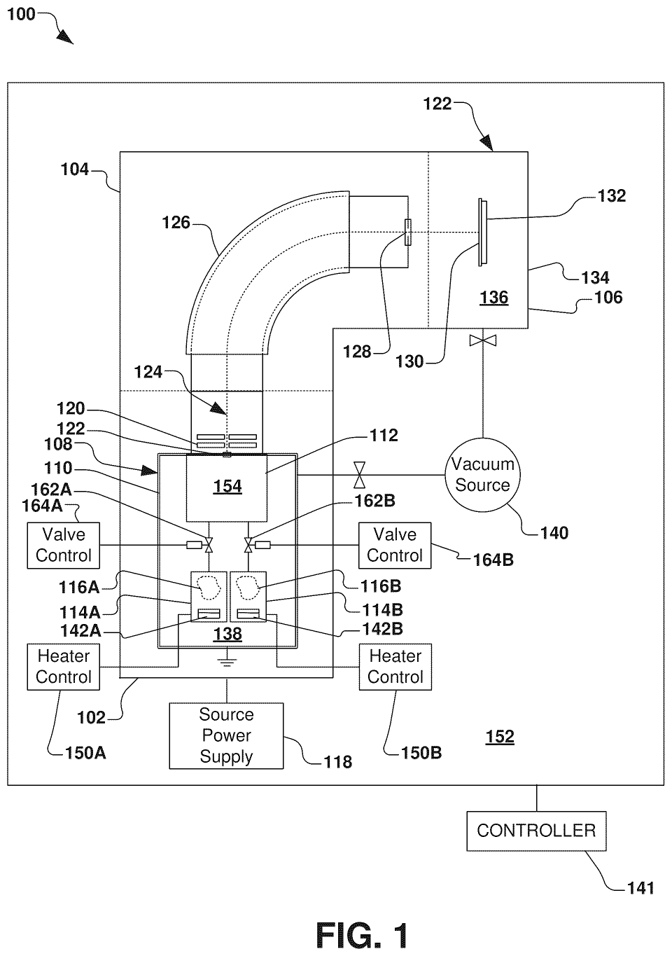

In order to provide an overview and to gain a better understanding of the disclosure, FIG. 1 illustrates an ion implantation system 100 in accordance with several example aspects of the disclosure. The ion implantation system 100 generally comprises a terminal 102, a beamline assembly 104, and an end station 106. An ion source 108 is positioned in the terminal 102, wherein the ion source 108, for example, comprises a source body 110 (e.g., a vacuum enclosure, also called a source enclosure) having an arc chamber 112 disposed therein. The source body 110, for example, can be maintained at various pressures, such as a vacuum pressure.

In the present example, the ion source 108 comprises one or more vaporizers 114A, 114B positioned within the source body 110, wherein the one or more vaporizers are configured to selectively provide a respective dopant vapor 116A, 116B to the arc chamber 112, as will be discussed in greater detail infra. The arc chamber 112, for example, is further coupled to a power supply 118, whereby the power supply is configured to ionize the dopant vapor 116A, 116B into a plurality of ions within the arc chamber. It is noted that the power supply 118 can comprise any number of power supplies operably coupled to the ion source 108. One or more electrodes 120 are configured to extract the ions from an extraction aperture 122 in the arc chamber 112 to form an ion beam 124. The one or more electrodes 120, for example, may be appropriately biased and configured to extract the ion beam 124 while inhibiting back streaming of neutralizing electrons back toward the arc chamber 112.

The ion beam 124 in the present example is directed through a beam-steering apparatus 126, and out an aperture 128 towards the end station 106. It is noted that the ion implantation system 100 of FIG. 1 is illustrated in a simplified manner, and that while not shown, additional apparatuses may be provided for directing, accelerating, decelerating, stripping, scanning, shaping, and/or otherwise manipulating the ion beam 124 as it travels toward the end station 106, as will be appreciated by one of skill in the art.

In the end station 106, the ion beam 124 bombards a workpiece 130 (e.g., a semiconductor wafer, a display panel, etc.), which is selectively clamped or mounted to a chuck 132 (e.g., an electrostatic chuck or ESC). Once embedded into the lattice of the workpiece 130, the implanted ions change the physical and/or chemical properties of the workpiece. Because of this, ion implantation is used in semiconductor device fabrication and in metal finishing, as well as various applications in materials science research. It is noted that the ion implantation system 100 is illustrated as just one example, and that the present disclosure can be practiced in a variety of vacuum systems, such as plasma processing systems, or other semiconductor processing systems. Further, the ion beam 124 of the present disclosure can take any form, such as a pencil or spot beam, a ribbon beam, a scanned beam, or any other form in which ions are directed toward end station 106, and all such forms are contemplated as falling within the scope of the disclosure.

According to one exemplary aspect, one or more of the terminal 102, beamline assembly 104, and end station 106 can comprise one or more vacuum chambers defining respective environments, therein. For example, the end station 106 can comprise a process chamber 134, wherein a process environment 136 is associated with the process chamber. The ion source 108, for example, can further have a source environment 138 associated with, and defined within, the source body 110. A vacuum source 140 (e.g., a vacuum pump) can be further provided to define a vacuum within the process environment 136, the source environment 138, and/or within any of the terminal 102, beamline assembly 104, and end station 106. Further, a controller 141 is provided for overall control of the ion implantation system 100.

The present disclosure appreciates that workpieces 130 having silicon carbide-based devices formed thereon have been found to have better thermal and electrical characteristics than silicon-based devices, in particular, in applications used in high voltage and high temperature devices, such as electric cars, etc. Ion implantation into silicon carbide, however, utilizes a different class of implant dopants than those used for silicon workpieces. In silicon carbide implants, for example, aluminum and nitrogen provide acceptable results. While nitrogen implants are relatively simple, as the nitrogen can be introduced as a gas from a gas bottle held at room temperature, few good bottled gaseous sources of aluminum are presently known.

Thus, in accordance with one example of the present disclosure, the one or more vaporizers 114A, 114B, for example, are configured to vaporize a respective base dopant ion species 142A, 142B (e.g., initially provided in either solid or liquid state) to form the respective dopant vapor 116A, 116B. The dopant ion species 142A, 142B can comprise the same species, or differing species, whereby the one or more vaporizers 114A, 114B can provide redundancy, alternative process recipe capabilities, or extend a lifetime of the provision of the species within the ion source 108.

In one example, the base dopant ion species 142A can comprise an aluminum-based source material such as solid (or powdered) aluminum chloride (AlCl₃), while the base dopant species 142B can comprise another aluminum-containing material, such as aluminum iodide (AlI₃) or other solid form material that is converted from solid or liquid state to the respective dopant vapor 116A, 116B in gaseous form by the respective vaporizers 114A, 114B. For example, when the base dopant species 142A comprises AlCl₃, the resulting dopant vapor can comprise AlCl₃ or (AlCl₃)₂. The present disclosure also contemplates any of the base dopant species 142A, 142B as also being advantageously used to generate of other species dopant vapor 116A, 116B, such as Gallium, Lanthanum, Indium, Antimony, Magnesium, Yttrium, and Ytterbium, whereby the base dopant species can be provided in solid or liquid state. In another alternative example, the dopant ion species 142A, 142B can comprise the same species, whereby the one or more vaporizers 114A, 114B can increase a time between maintenance of the ion source 108.

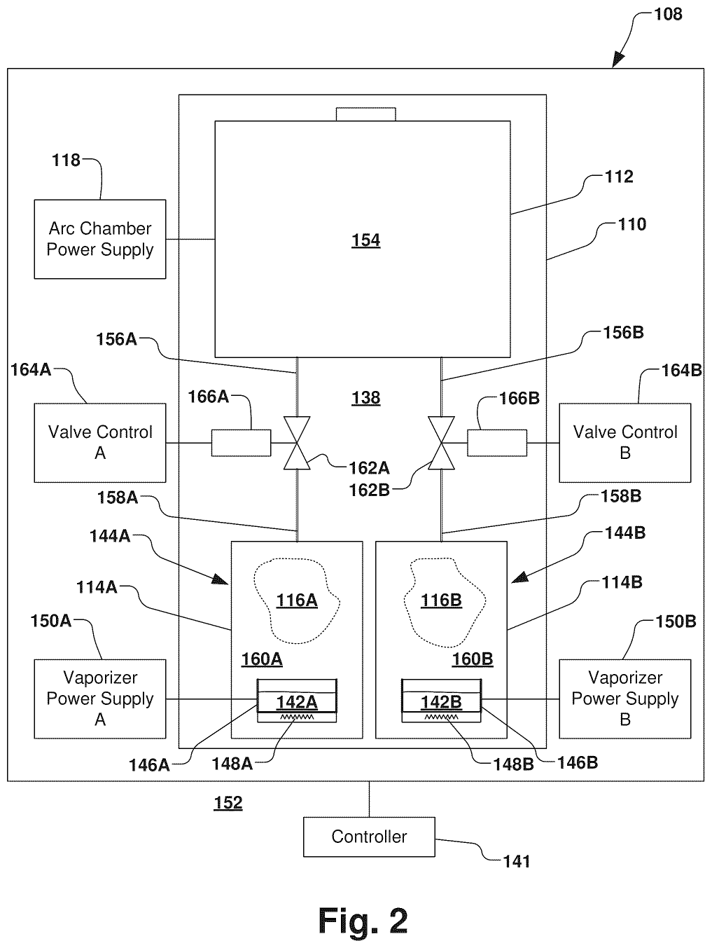

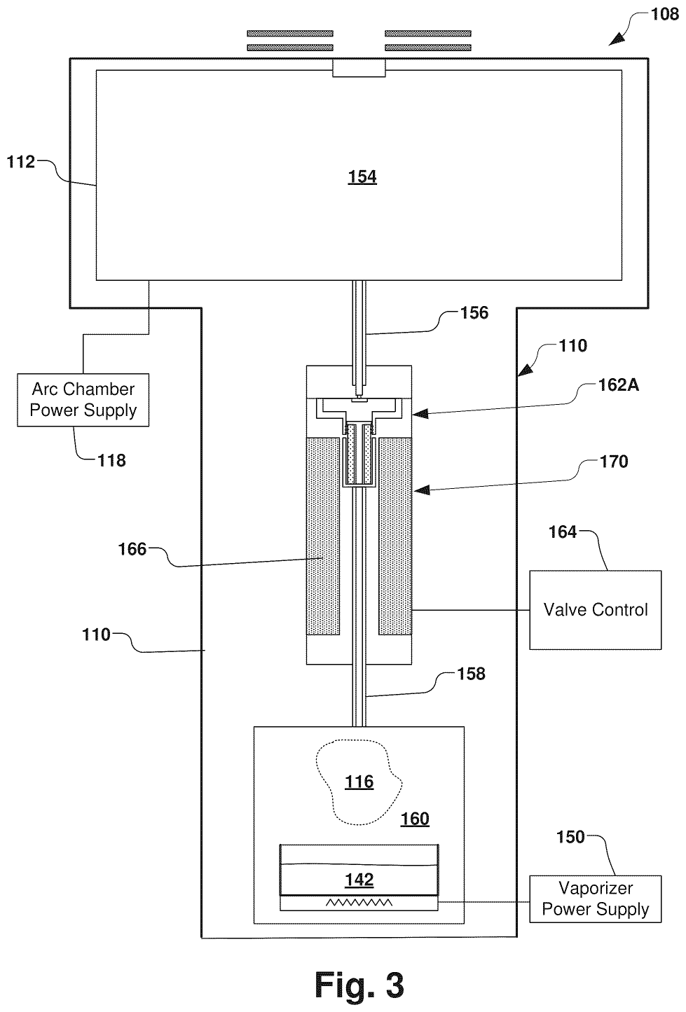

The present example provides each of the vaporizers 114A, 114B having similar componentry. It shall be noted, however, that while two vaporizers 114A, 114B are shown, the ion source 108 of FIG. 1 can comprise any number of vaporizers 114, and each of the vaporizers can have unique or similar componentry, as long as each is vaporizer is respectively configured to provide the respective dopant vapor 116 to the arc chamber 112. For instance, FIG. 2 illustrates the ion source 108 of FIG. 1 having two vaporizers 114A, 114B in accordance with one example, while FIGS. 3-5 illustrate a single vaporizer 114 in accordance with various other examples, as will be discussed infra.

As illustrated in FIG. 2, for example, each of the vaporizers 114A, 114B comprises a respective cylindrical oven 144 positioned within the source body 110 and within the source environment 138 (e.g., a vacuum environment), whereby the base dopant species 142A, 142B is heated in a respective crucible 146A, 146B by one or more respective heating coils 148A, 148B. The heating coils 148A, 148B, for example, are selectively heated by a respective heater control circuit 150A, 150B, which may comprise a power supply, temperature sensor, logic controller, and/or other control apparatus configured to selectively heat the respective crucible 146A, 146B, and thus, the respective base dopant species 142A, 142B, to a predetermined temperature or vapor pressure. It is noted that componentry of the heater control circuit 150A, 150B may be shared or duplicated between the vaporizers 114A, 114B, as will be appreciated by one of ordinary skill. It is further noted that while heating coils 148A, 148B are described in the present example for selectively heating the respective crucible 146A, 146B, the present disclosure contemplates various other heat sources for selectively heating the respective crucible, such as heating by one or more lamps or other radiative, conductive, or convective heat sources (not shown), whereby such other heat sources can be similarly controlled by the respective heater control circuit 150A, 150B.

The vaporizers 114A, 114B positioned in the source body 110 of the ion source 108, for example, can be loaded with the respective base dopant species 142A, 142B in an inert environment (e.g., argon, nitrogen, etc.) so as not to react with gases or moisture in an atmospheric environment 152 external to the source body. For example, the source body 110 can be selectively removed from the terminal 102 of FIG. 1, whereby the vaporizers 114A, 114B can be loaded with the base dopant species 142A, 142B. The source body 110 can then be re-installed in the terminal and pumped down by the vacuum source 140 to the operating pressure of the ion implantation system 100.

The arc chamber 112 positioned within the source body 110, for example, has an arc chamber environment 154 (e.g., a vacuum environment) defined therein, wherein one or more arc chamber conduits 156A, 156B, for example, are in fluid communication with the arc chamber environment. It is noted that the one or more arc chamber conduits 156A, 156B can comprise a single conduit having multiple paths define therein. Further, one or more vaporizer conduits 158A, 158B are provided in fluid communication with the respective vaporizers 114A, 114B and vaporizer environments 160A, 160B defined therein. In accordance with the present disclosure, one or more valves 162A, 162B are positioned within the source body 110 and are fluidly coupled to the respective arc chamber conduits 156A, 156B and the vaporizer conduits 158A, 158B. The one or more valves 162A, 162B, for example, are configured to selectively control a respective flow of the respective dopant vapors 116A, 116B from the vaporizer environments 160A, 160B to the arc chamber environment 154.

In accordance with one example aspect of the disclosure, the one or more valves 162A, 162B, for example, comprise one or more automated valves configured to control the flow of the respective dopant vapor 116A, 116B from the respective vaporizer environment 160A, 160B to the arc chamber environment 154. The control of the one or more valves 162A, 162B, for example, can be respectively accomplished by one or more valve controllers 164A, 164B, and/or the controller 141, wherein the control of the one or more valves is based, at least in part, on one or more desired arc chamber conditions associated with the arc chamber 112. For example, the one or more valve controllers 164A, 164B, and/or the controller 141 is configured to control the respective valves 162A, 162B to selectively control the flow of the respective dopant vapor 116A, 116B from the respective vaporizer 144A, 144B to the arc chamber environment 154.

The one or more valves 162A, 162B, for example, can each respectively comprise a solenoid valve 166A, 166B. For example, each valve controller 164A, 164B controller is configured to selectively control a duty cycle of the respective solenoid valve 166A, 166B (e.g., the percentage of time that the respective solenoid valve is open). As such, each valve controller 164A, 164B is configured to selectively control the flow of the respective dopant vapor 116A, 116B from the respective vaporizer 144A, 144B to the arc chamber environment 154, whereby the respective flow can be selectively variable. A maximum operating frequency (also called a switching frequency) of the respective solenoid valve 166A, 166B can be defined as the number of times the respective solenoid valve is opened and closed per second, and can be on the order of hundreds of Hertz, thus providing accurate control of the flow. By providing the switching frequency of the respective solenoid valve 166A, 166B on the order of hundreds of hertz, a flow of the respective dopant vapor 116A, 116B through the respective arc chamber conduits 156A, 156B to the arc chamber environment 154 can appear to be generally constant, as opposed to a series of pulses.

Each solenoid valve 166, for example, can comprise a ball and a sealing surface configured to selectively flow the dopant vapor from the vaporizer environment to the arc chamber environment 154 based on a position of the ball with respect to the sealing surface.

The present disclosure appreciates that available space in the ion source 108 is limited due to structural and cost constraints. Thus, the one or more valves 162A, 162B of the present disclosure can be provided in the form of a miniature solenoid valve configured to operate at temperatures up to approximately 150° C. The miniature solenoid valve, for example, can be comprised of a corrosion-resistant material such as stainless steel and other material suitable for ion implantation.

The miniature solenoid valve, for example, can comprise a solenoid valve configured to translate a ball with respect to a sealing surface, whereby the translation of the ball is translated via a current passed through a coil. Alternatively, the miniature valve comprises a hydraulic valve, a compression valve, or a butterfly valve.

In accordance with a preferred embodiment, the one or more valves 162A, 162B, for example, can respectively comprise an electrically controlled solenoid valve configured to actuate at high speeds (e.g., actuation speeds on the order of hundreds of Hz), whereby a flow of between zero and a predetermined maximum (e.g., 100% of flow based on flow characteristics of the conduit) can be achieved by varying a duty cycle of the valve, which is defined as the fraction of the time that the valve is in the open position. The valve apparatus, for example, can further comprise a relief feature (e.g., a relief valve), whereby pressure is relieved beyond a predetermined pressure limit in the event of failure of the miniature valve.

The one or more valves 162A, 162B, for example, are configured to modulate the flow of the vapor through the respective arc chamber conduits 156A, 156B and the vaporizer conduits 158A, 158B between 0% and 100% of the predetermined maximum by control of the duty cycle of the valve by an electrical drive circuit (e.g., the associated valve controller 164A, 164B) associated with the respective valve. As such, the present disclosure provides expedient switching between flowing a plurality of vapor species from one or more vaporizers to the arc chamber 112, such as when switching between singly-charged and multiply-charged species of vapors for operation of the arc chamber. The one or more valves 162A, 162B of the present disclosure, for example, can thus fully halt the flow of dopant species 142A from the vaporizer 114A to the arc chamber 112 when dopant species 142B is desired to be provided to the arc chamber from the vaporizer 114B or another vapor source (e.g., a gas source or another vaporizer).

Thus, it is possible to maintain the vaporizers 114A, 114B at an elevated temperature above the temperature required to generate the vapor pressure of dopant species needed to supply the ion source, enabling more robust control of the vaporizer temperature.

Thus, the flow of the dopant vapor 116 from the vaporizer 114 and the heating or other parameters used to control ion production within the arc chamber 112, as well as the general parameters of the ion source 108, for example, can be advantageously used to control the relative contributions of ions from sources of various dopant species, whereby the operation and output of the ion source can be advantageously tailored to suit particular ion implantation processing. For example, production of ions of a particular charge state can be advantageously maximized.

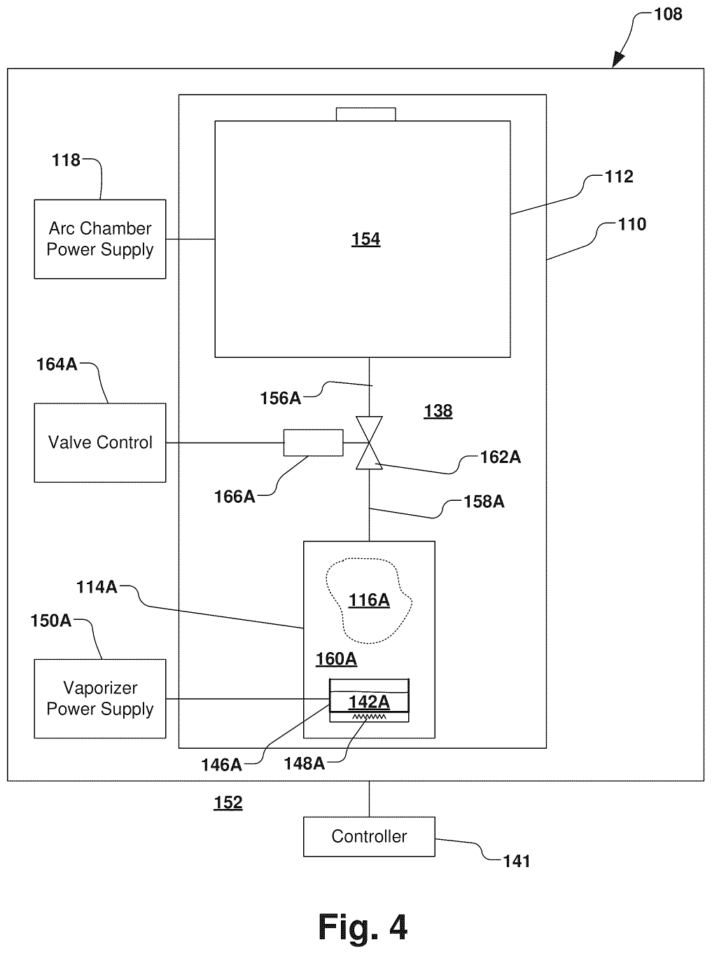

As illustrated in the example shown in FIG. 3, the first valve 162A is illustrated as comprising a miniature solenoid valve 170. In the example of FIG. 3, the first valve 162A is provided in the source body 110 of the ion source 108, whereby no second valve is provided. FIG. 4 illustrates another example showing the ion source 108 with just the first valve 162A and no second valve, whereby the first valve can be configured in any of the manners described above.

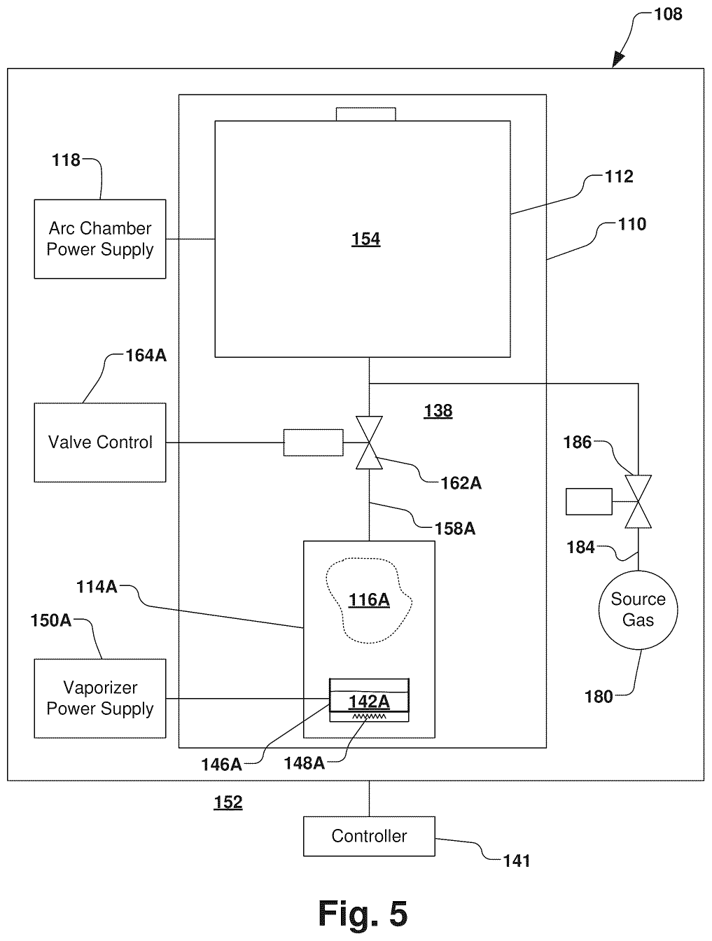

FIG. 5 illustrates another example of the ion source 108, whereby a dopant gas source 180 is further provided. A dopant gas conduit 184, for example, provides selective fluid communication with the dopant gas source 180 and a dopant gas valve 186 that is configured to selectively fluidly couple the dopant gas source to the arc chamber 112 via the dopant gas conduit. The dopant gas source 180, for example, can comprise a gas bottle or other gas supply containing a dopant gas species in gaseous form. The dopant gas source 180, for example, can comprise a nitrogen bottle or other supply of another gaseous species in compressed gaseous form.

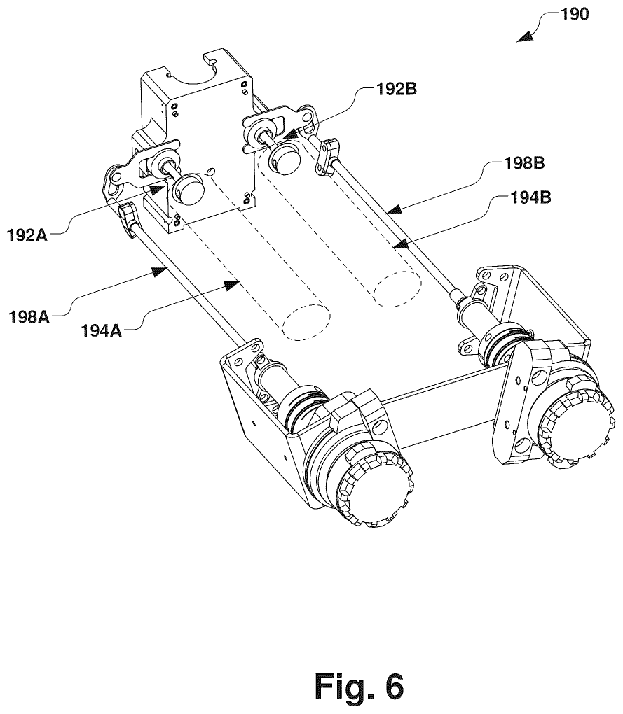

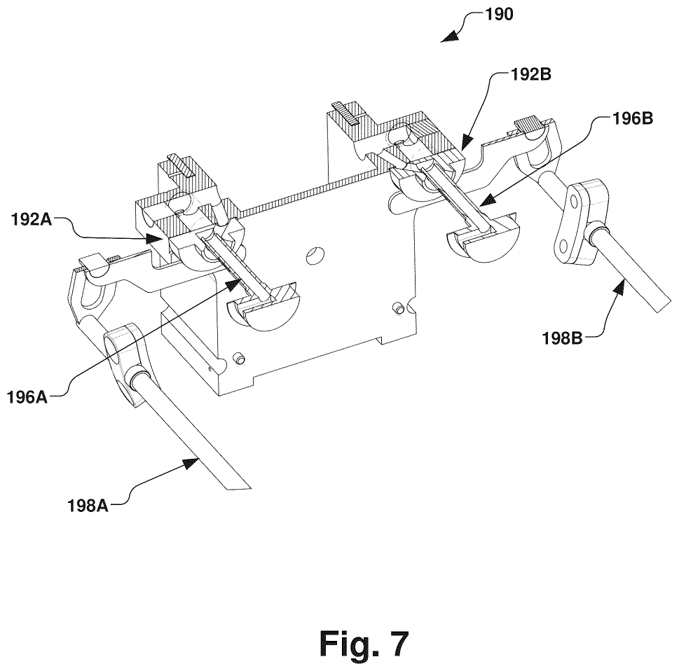

The one or more valves 162A, 162B, for example, can each respectively comprise one or more manual valves. A mechanical vaporizer valve apparatus 190, for example, is illustrated in FIGS. 6-7. In the example illustrated in FIG. 6, a respective manual valve 192A, 192B is respectively associated with each of a pair of vaporizers 194A, 194B that are positioned within the source body 110 of FIG. 1. A vaporizer nozzle at an output of the vaporizer (illustrated in phantom) is configured to be fluidly coupled to a vaporizer conduit. The vaporizer conduit is fluidly coupled to a mechanical valve (e.g., a plunger valve, butterfly valve, etc.), whereby the mechanical valve is further fluidly coupled to an arc chamber conduit that is in fluid communication with the arc chamber. Each valve is operably coupled to a linkage (e.g., one or more rods). Actuation of the valve, for example, can be achieved by a manual manipulation of the valve by an operator, or by automation, such as by electrical, pneumatic, or hydraulic actuation.

For example, the mechanical vaporizer valve apparatus 190 can comprise a plunger valve 196A, 196B illustrated in FIG. 7, whereby the plunger valve can be actuated by an actuator rod or linkage 198 operably coupled to the plunger valve. The plunger valve thus selectively fluidly couples the vaporizer to the arc chamber via a translation or other motion of the actuator rod, thereby selectively engaging and disengaging an engagement member of the valve with a valve seat, whereby a communicating channel through the engagement member thus selectively fluidly couples the vaporizer to the arc chamber. The valve, for example, can be comprised of one or more of graphite, tungsten, tantalum, molybdenum or other material configured to resist the high temperature and chemically-corrosive environment within the ion source.

According to one example, the plunger valve can provide continuous or graduated motion to allow for partial opening thereof to vary the conductance between vaporizer and arc chamber. Further, an auxiliary channel can be provided, whereby a relief is provided to permit the valve to exhaust or divert vapor to an external environment. As such, an over-pressurization, relief, and/or release of vapor can be achieved for safety purposes, or if completely closing off the vaporizer is not desirable due to deposition in the valve.

Further, an orifice or other flow limitation apparatus can be provided in a unitary arc chamber conduit that is in fluid communication with the arc chamber environment, whereby a plurality of valves are configured to select a respective one of a plurality of vaporizers to be fluidly coupled to the orifice.

In another example, an auxiliary chamber is provided proximate to the arc chamber between the valve and the arc chamber. The auxiliary chamber, having a volume larger than the volume of gas fed to the chamber by each pulse of the valve in pulsed operation, serves to reduce variations in gas flow to the source and to smooth a pulsation associated with cycling of the valve.

While gaseous precursors of an ion species are preferred for ionization by an ion source for ion implantation, some species of technological interest (e.g. Al, Sb, In, Ga) are not conventionally available in convenient gaseous forms. In such cases, a solid form of the species may be heated in a crucible of a vaporizer in order to generate a vapor at a temperature having a vapor pressure sufficient to sustain a plasma. The vapor is then fed to an arc chamber of the ion source in which the plasma is formed. Vaporizers may electrically or radiatively heat the crucible, and the vaporizer may be located either inside or outside of a vacuum environment of the ion source. Conventionally, a vaporizer is positioned inside an ion source body and is fluidly coupled to the arc chamber via a feed tube comprised of graphite, tungsten, tantalum, or a similar refractory material, whereby a flow of the vapor from the vaporizer to the arc chamber is indirectly controlled by controlling the temperature of the crucible holding the species material. A temperature sensor is typically located near the crucible to control the average heating power supplied to the crucible. Conventional ion implanter systems can support up to two vaporizer systems in the ion source body, whereby the two vaporizer systems can supply different respective species to the arc chamber, or increase the available volume for vaporization of a single species supplied to the arc chamber, whereby only one vaporizer is typically operational at any given time.

Conventionally, the crucible is in constant open fluid communication with the arc chamber via the feed tube. When it is desired to halt the provision of a species to the arc chamber, the temperature of the crucible is reduced in order to reduce the flow of vapor of the species into the arc chamber. As such, a potential cross-contamination of species in the plasma is reduced when changing vaporizers. When the species contained in the vaporizer is next desired to be run, the temperature of the crucible is again increased to vaporize the species at the desired vapor pressure and flow the vapor to the arc chamber.

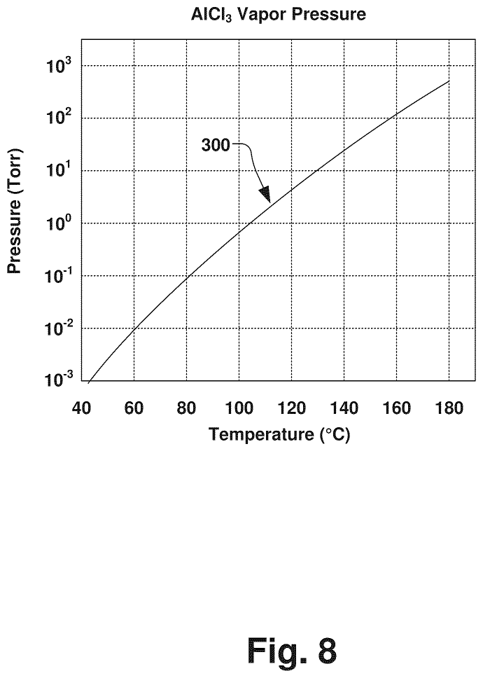

Vapor pressure has a strong (e.g., exponential) dependence on temperature, as illustrated in vapor pressure curve 300 for aluminum chloride shown in FIG. 8. As such, even a small change in the crucible temperature of the vaporizer can significantly reduce or increase the flow of the vapor to the arc chamber. As such, when warming the crucible to a target temperature, significant care should be taken to not exceed the target temperature in order to avoid excessive vapor to the arc chamber. When an available heating power to be supplied to the crucible is on the order of a few hundred watts, for example, a mass of the vaporizer assembly in which the crucible resides can lead to a response time of several minutes for heating the crucible accurately. As a result, initiating and halting the flow of vapor in a vaporizer can take on the order 10 minutes. When it is desired to extract multiply-charged ions from a plasma source, gas pressure in the ion source can also be reduced for forming the resulting ion beam. As a result, switching between singly-and multiply-charged ion beams of the same species can require changes in the vaporizer temperature, whereby similar transition times can result.

The present disclosure thus provides a vaporizer valve apparatus having electrically-controlled flow, whereby the valve apparatus, for example, is configured to operate at temperatures up to approximately 150° C., thus advantageously allowing for low-temperature materials such as AlI₃ and AlCl₃. The present disclosure, for example, can further advantageously maintain the temperature of the vaporizer above ambient temperature and at a temperature greater than temperatures produced by thermal transmission from the arc chamber, thus providing greater control of the temperature of the vaporizer.

The present disclosure, for example, can provide short transition times to and from vaporizer sources of material and other species. For example, the vaporizer can be held at a constant operating temperature, whereby the supply of vapor to the arc chamber can be halted or otherwise controlled without lowering the temperature of the vaporizer.

Still further, the present disclosure advantageously provides short transition times between singly-charged and multiply-charged ion species from the vaporizer material, as the supply of vapor from the vaporizer to the arc chamber may be quickly controlled. Cross-contamination from a species provided in the vaporizer can be further minimized, as the flow of vapor from the vaporizer to the arc chamber can be entirely halted when other species are desired to be provided to the arc chamber. Further, the conduit between valve apparatus and the arc chamber is advantageously heated by conduction from the arc chamber, whereby the present disclosure does not necessitate additional heating of the conduit to prevent condensation of the vapor in the conduit.

Furthermore, the vapor pressure curve 300 for aluminum chloride (AlCl₃) illustrated in FIG. 8, for example, can be utilized for selecting a valve for flowing the vapor to the arc chamber. As can be seen on the curve 300, at a maximum rated temperature for an exemplary valve of 135° C., the aluminum chloride material has a vapor pressure of approximately 30 Torr. As such, a selection of such an exemplary valve can be made such that a predetermined control of flow of the vapor to the arc chamber can be achieved. In the present example, the exemplary valve would be able to control a flow of up to approximately 15 sccm of the vapor to the arc chamber, which is in an acceptable range for an ion source in an implanter.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An ion source for an ion implantation system, the ion source comprising:
a vacuum enclosure defining a vacuum environment therein;
an arc chamber generally defining an arc chamber environment therein, wherein the arc chamber is positioned within the vacuum enclosure and comprises an arc chamber conduit in fluid communication with the arc chamber environment;
a first vaporizer positioned within the vacuum enclosure and configured to selectively vaporize a first dopant species to define a first dopant vapor within a first vaporizer environment defined therein, and wherein the first vaporizer comprises a first vaporizer conduit in fluid communication with the first vaporizer environment; and
a first valve positioned within the vacuum enclosure and fluidly coupled to the arc chamber conduit and the first vaporizer conduit, wherein the first valve is configured to selectively control a flow of the first dopant vapor from the first vaporizer environment to the arc chamber environment.

2. The ion source of claim 1, further comprising a controller, wherein the first valve comprises a first automated valve, and wherein the controller is configured to control the first automated valve to selectively control the flow of the first dopant vapor from the first vaporizer environment to the arc chamber environment, wherein the control of the first automated valve is based, at least in part, on one or more desired arc chamber conditions associated with the arc chamber.

3. The ion source of claim 2, wherein the first automated valve comprises a solenoid valve.

4. The ion source of claim 3, wherein the controller is configured to control a duty cycle of the solenoid valve, thereby selectively controlling the flow of the first dopant vapor from the first vaporizer environment to the arc chamber environment, wherein the flow of the first dopant vapor from the first vaporizer environment to the arc chamber environment is selectively variable between zero and 100%.

5. The ion source of claim 1, further comprising a second vaporizer positioned within the vacuum enclosure and configured to selectively vaporize a second dopant species to define a second dopant vapor within a second vaporizer environment defined therein, and wherein the second vaporizer comprises a second vaporizer conduit in fluid communication with the second vaporizer environment.

6. The ion source of claim 5, further comprising a second valve positioned within the vacuum enclosure and fluidly coupled to the arc chamber and the second vaporizer conduit, wherein the second valve is configured to selectively control a flow of the second dopant vapor from the second vaporizer environment to the arc chamber environment.

7. The ion source of claim 6, further comprising a controller, wherein the first valve comprises a first automated valve, wherein the second valve comprises a second automated valve, and wherein the controller is configured to control the first automated valve and the second automated valve to respectively selectively control the flow of the first dopant vapor from the first vaporizer environment to the arc chamber environment and the second dopant vapor from the second vaporizer environment to the arc chamber environment, based, at least in part, on one or more desired arc chamber conditions associated with the arc chamber.

8. The ion source of claim 7, wherein one or more of the first automated valve or the second automated valve comprises a respective solenoid valve.

9. The ion source of claim 8, wherein the controller is configured to control a duty cycle of the respective solenoid valve.

10. The ion source of claim 8, wherein the controller is further configured to control a switching frequency of the respective solenoid valve, wherein the switching frequency is on the order of hundreds of Hertz.

11. The ion source of claim 7, wherein one or more of the flow of the first dopant vapor from the first vaporizer environment to the arc chamber environment or the flow of the second dopant vapor from the second vaporizer environment to the arc chamber environment is selectively variable between zero and 100%.

12. The ion source of claim 5, wherein the first dopant species is configured to define singly-charged ions in the arc chamber, and wherein the second dopant species is configured to define multiply-charged ions in the arc chamber.

13. The ion source of claim 1, wherein the first valve is configured to control the flow of the first dopant vapor from the first vaporizer environment to the arc chamber environment based, at least in part, on a first vaporizer temperature associated with the first vaporizer environment.

14. The ion source of claim 13, wherein the first valve is configured to selectively prevent the flow of the first dopant vapor from the first vaporizer environment to the arc chamber environment when the first vaporizer temperature is greater than a first predetermined temperature.

15. The ion source of claim 14, wherein the first predetermined temperature is approximately 150° C.

16. The ion source of claim 1, wherein the first vaporizer comprises a crucible and a crucible heater, wherein the crucible is configured to generally contain the first dopant species in one or more of a solid state and a liquid state, and wherein the crucible heater is configured to selective heat the crucible to a predetermined vaporization temperature.

17. The ion source of claim 1, wherein the first dopant species comprises aluminum.

18. The ion source of claim 1, wherein the first dopant vapor comprises AlCl₃ or (AlCl₃)₂.

19. The ion source of claim 1, wherein the first valve further comprises a first relief valve in selective fluid communication with the vacuum environment, wherein the first relief valve is configured to exhaust the first vaporizer to the vacuum environment when a first vaporizer pressure within the first vaporizer environment exceeds a predetermined pressure.

20. An ion source for an ion implantation system, the ion source comprising:
a vacuum enclosure defining a vacuum environment therein;
an arc chamber generally defining an arc chamber environment therein, wherein the arc chamber is positioned within the vacuum enclosure and comprises an arc chamber conduit in fluid communication with the arc chamber environment;
a first vaporizer positioned within the vacuum enclosure and configured to selectively vaporize a first dopant species to define a first dopant vapor within a first vaporizer environment defined therein, and wherein the first vaporizer comprises a first vaporizer conduit in fluid communication with the first vaporizer environment;
a first solenoid valve positioned within the vacuum enclosure and fluidly coupled to the arc chamber conduit and the first vaporizer conduit, wherein the first solenoid valve is configured to selectively control a flow of the first dopant vapor from the first vaporizer environment to the arc chamber environment;
a second vaporizer positioned within the vacuum enclosure and configured to selectively vaporize a second dopant species to define a second dopant vapor within a second vaporizer environment defined therein, and wherein the second vaporizer comprises a second vaporizer conduit in fluid communication with the second vaporizer environment.
a second solenoid valve positioned within the vacuum enclosure and fluidly coupled to the arc chamber and the second vaporizer conduit, wherein the second solenoid valve is configured to selectively control a flow of the second dopant vapor from the second vaporizer environment to the arc chamber environment; and
a controller configured to control the first solenoid valve and the second solenoid valve to respectively selectively control the flow of the first dopant vapor from the first vaporizer environment to the arc chamber environment and the second dopant vapor from the second vaporizer environment to the arc chamber environment, based, at least in part, on one or more desired arc chamber conditions associated with the arc chamber.
